(19) United States
(12) Patent Application Publication
(10) Pub. No.: US 2006/0208916 A1
(43) Pub. Date: Sep. 21, 2006

(54) Components for gas sensor device

(76) Inventors: Patricia A. Morris, Montchanin, DE (US); Alfred T. Walker, Oxford, PA (US); Peter A. Booth, Harwich, MA (US); David R. Murphy, Noha Attleboro, MA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/297,018

(22) Filed: Dec. 8, 2005

Related U.S. Application Data
(60) Provisional application No. 60/634,461, filed on Dec. 9, 2004.

(51) Int. Cl. G08B 17/10; H02J 3/00; H03K 19/177

(52) U.S. Cl. 340/632; 326/41; 307/11

(57) ABSTRACT

Disclosed herein is a space-saving arrangement for sensor elements, electrodes and conductors, and an encasement therefore, in a gas sensitive apparatus.

This application claims the benefit of U.S. Provisional Application No. 60/634,461, filed Dec. 9, 2004, which is incorporated in its entirety as a part hereof for all purposes.

### TECHNICAL FIELD

This invention relates to the use in a device (such as a gas sensor device) of components such as a gas sensitive apparatus, an electrically conductive apparatus and/or an encasement for the electrically conductive apparatus. The gas sensor device is particularly, but not exclusively, useful for the analysis of a gas mixture such as that which is emitted in the form of automotive exhaust, or that, which is emitted from other kinds of internal combustion engines. Each apparatus of this invention is particularly advantageous in view of its applicability to, or in conjunction with, the detection or quantitative determination of individual gases present in a mixture, its compact size, and its low power consumption.

### BACKGROUND

In an automotive engine, it is advantageous to be able to detect the presence or concentration of the various components in the exhaust gas stream. Such analysis and measurement can be used for controlling the operation of the engine, with a view toward optimizing the amounts of injected air and fuel. If the engine can be provided with an optimal composition of the air/fuel mixture during all operating conditions, the fuel consumption and the harmful emissions from the engine can be minimized. In addition to engine control, gas analysis and measurement can also play a role in the diagnosis of the condition and performance of the automotive catalytic converter. The oxygen and hydrocarbon levels in the exhaust gas stream should generally lie within certain ranges for the optimum performance of the catalytic converter.

A variety of gases are typically present in an automotive engine exhaust stream, including, for example, oxygen, nitrogen oxide compounds (NOx), carbon monoxide, sulfur oxides (SOx), hydrogen sulfide (H₂S), hydrocarbons, ammonia, hydrogen and water. Numerous products are known that are intended to analyze a stream of gas using a gas sensor device. A typical gas sensor device employs as sensor element(s) one or more chemo/electro-active materials, each of which is a material that will exhibit a change in an electrical property upon exposure to a gas.

A complicating factor in the process of analyzing and measuring the wide variety of gaseous components in a mixture such as exhaust gas is that the signal from one particular sensor element can be influenced by its exposure to gases other the gas(es) for which its signal is intended to serve as the desired analytical data. For example, a material selected as a sensor to respond to NOx, apart from detecting the presence or concentration of a nitrogen oxide compound, may also be sensitive to the presence of oxygen or a hydrocarbon. This difficulty has been addressed by simultaneously using a plurality of different types of sensor elements to generate enough data to permit separation of those signals that are accurately reflective of the presence of an analyte gas from those that are the unavoidable result of the cross-sensitivity of the different sensor elements to the total population of gases.

A gas sensor device constructed with a sufficient number of different sensor elements to adequately address such problem of cross-sensitivity may, however, be subject to size limitations depending on the nature of its deployment. If the gas sensor device will be used for automotive purposes, it will be subject to very strict and demanding size limitations. Many currently known automotive gas sensors, such as that described for example in U.S. Pat. No. 5,556,526, must be small enough to pass through a circle having a diameter of no more than 100 mm, if not smaller. On-board automotive diagnostics is, however, not the only use for a gas analyzer having compact size as hand-held devices for monitoring all varieties of toxic and hazardous gaseous materials are becoming increasingly important.

When constructing a size-limited gas sensor, there is consequently an inevitable tension between the desire to utilize as many different sensor elements in the device as possible, and the need for the sensor device to meet the applicable size limitation. Each separate sensor element raises considerations of not only the space occupied by the element itself, but the location and arrangement of the conductors, connectors and cabling that carry the input and output pulses and signals necessary to operate all of the sensor elements that are contained in the sensor device. This has resulted in a need to develop components for the device, such as a gas sensitive apparatus and an electrically conductive apparatus, that enable increasing the number of sensor elements that can be used in the sensor device while maintaining the size of the device within permitted limits.

The present invention meets this need as it provides a gas sensitive apparatus and/or an electrically conductive apparatus for use as component(s) in a gas sensor device that will contain a desirably high number of sensor elements and yet meet virtually all applicable size limitations for use for automotive purposes or in other desired industrial settings. The use of the gas sensitive apparatus of this invention in a gas sensor device is, of course, not limited to components for the automotive industry. The use of the electrically conductive apparatus of this invention is not limited to a gas sensor device, but may be used in other kinds of electrical devices.

One particular advantage of this invention is that it provides, in a gas sensitive apparatus, a space-saving arrangement for a large number of sensor elements, and the electrodes (such as printed electrodes) that are associated therewith. Another advantage of this invention is that it provides in an electrically conductive apparatus a space-saving arrangement for a plurality of conductors that are sufficient in number to carry pulse and signal inputs and outputs to and from the many electrodes and sensor elements. Yet another advantage of this invention is that it provides an encasement for such plurality of conductors. By incorporating a large number of sensor elements in a compact, small-sized gas sensitive apparatus, and by providing a compact arrangement of conductors with which to operate a large number of sensor elements, the present invention enables the discrimination of very low concentrations of a wide variety of components in a gas mixture under conditions of virtually any size limitation. The gas sensitive apparatus and/or electrically conductive apparatus is incorporated into a gas sensor device that is installed in an automotive vehicle or any other desired type of industrial equipment. These and other advantages are more particularly described below.

### SUMMARY

One embodiment of this invention is a gas sensitive apparatus that includes (a) sensor elements, (b) and conductors that provide electrical current to the sensor elements, wherein the ratio of the number of conductors to the number of sensor elements is no greater than about 0.585.

Another embodiment of this invention is a gas sensitive apparatus that includes (a) a substrate that comprises a plurality of sensor elements, and (b) a conductor that comprises a plurality of conductive members; wherein (i) a first conductive member contacts a first surface of the substrate, (ii) a second conductive member contacts a second surface of the substrate, and (iii) the first and second conductive members are attached to a common support member.

A further embodiment of this invention is an electrically conductive apparatus that includes first and second sets of conductors that contact a substrate containing electrodes, wherein (a) a first portion of each of the members of the first and second sets of conductors is adjacent to a first surface of the substrate, and together define a first plane, (b) a second portion of each of the members of the first set of conductors together define a second plane that is separate from and substantially parallel to the first plane, and (c) a second portion of each of the members of the second set of conductors together define a third plane that is separate from and substantially parallel to the first and second planes.

Yet another embodiment of this invention is an electrically conductive apparatus comprising first, second and third sets of conductors that contact a substrate containing electrodes, wherein (a) a first portion of each of the members of the first and second sets of conductors is adjacent to a first surface of a substrate, and together define a first plane, (b) a second portion of each of the members of the first set of conductors together define a second plane that is separate from and substantially parallel to the first plane, and (c) a first portion of each of the members of the third set of conductors together define a third plane that is separate from and substantially parallel to the first and second planes.

Yet another embodiment of this invention is an electrically conductive apparatus comprising first and second sets of conductors that contact a substrate containing electrodes, wherein (a) a portion of all members of the first and second sets of conductors are adjacent to a first surface of the substrate, (b) the substrate defines a first plane, (c) a portion of each of the members of the first set of conductors together define a second plane that is separate from and substantially parallel to the first plane, and (d) a portion of each of the members of the second set of conductors together define a third plane that is separate from and substantially parallel to the first and second planes.

Yet another embodiment of this invention is an, electrically conductive apparatus comprising first and second sets of conductors that contact a substrate containing electrodes; wherein (a) a first portion of each member of the first set of conductors, and a first portion of each member of the second set of conductors, is adjacent to a surface of the substrate, (b) a second portion of each of the members of the first set of conductors together define a first plane, (c) a second portion of each of the members of the second set of conductors together define a second plane that is separate from and substantially parallel to the first plane, and (d) the first portion of each member of the first and second sets of conductors is attached to a common support member.

Yet another embodiment of this invention is an electrically conductive apparatus comprising first and second sets of conductors; wherein (a) each set of conductors contacts a surface of a substrate, (b) a first portion of each member of the first set of conductors contacts a first surface of the substrate, (c) a first portion of each member of the second set of conductors contacts a second surface of the substrate, (d) a second portion of each member of the first and second sets of conductors is connected to an electrical power supply, and (e) the first portion of each member of the first and second sets of conductors is attached to a common support member.

Yet another embodiment of this invention is an encasement for a substrate and for a plurality of conductors, each conductor having first and second portions; wherein the encasement comprises (a) an aperture shaped to press the first portion of each conductor in contact with a surface of the substrate; and (b) a separate aperture for the second portion of each conductor.

Yet another embodiment of this invention is an encasement for a substrate and for first and second sets of conductors; wherein (a) each conductor has first and second portions; (b) the first portion of each conductor contacts a surface of the substrate; (c) the encasement comprises a separate aperture for the second portion of each conductor; (d) the apertures for the second portion of each of the members of the first set of conductors together define a first plane, and (e) the apertures for the second portion of each of the members of the second set of conductors together define a second plane that is separate from and substantially parallel to the first plane.

### DESCRIPTION OF THE DRAWINGS

FIG. 1 shows a schematic layout of sensor elements on a substrate.

FIG. 2A is a perspective view of a conductor.

FIG. 2B is a perspective view of a portion of a conductor and a substrate with which the conductor is in contact.

FIG. 3A is a perspective view of a conductor.

FIG. 3B is a perspective view of a portion of a conductor and a substrate with which the conductor is in contact.

FIG. 4A is a perspective view of a conductor.

FIG. 4B is a perspective view of a portion of a conductor and a substrate with which the conductor is in contact.

FIG. 5 is a side elevation view of a conductor and a substrate with which the conductor is in contact.

FIG. 6 shows a substrate, a conductor and an encasement for the conductor in an alignment by which the conductor may contact the substrate and the conductor may be inserted into the encasement.

FIG. 7 shows an encasement for a conductor with a substrate inserted therein and with a portion of a conductor protruding therefrom.

FIG. 8 shows an encasement for a conductor with a substrate inserted therein and with a portion of a conductor protruding therefrom.

FIG. 9 is a side elevation view of an encasement for a conductor.

### DETAILED DESCRIPTION

One embodiment of this invention is a gas sensitive apparatus that is useful for analyzing a mixture of gases such as those contained in the exhaust gas of an internal combustion engine, wherein the apparatus may contain a plurality of sensor elements. The sensor elements may be mounted on a substrate such as a unitary body or a multi-layer laminate for detecting specific gases contained in the mixture, and generating signals based thereon. A substrate that is a unitary body is fabricated from a material such as alumina or zirconia as one solid piece of stock and is not fabricated by building up a plurality of discrete layers. A multi-layered laminate by contrast is fabricated by the assembly of a plurality of layers that are bonded together by treatment with heat and pressure. The substrate is often planar in shape such that its cross section, looking in the direction of the largest dimension of the substrate, forms a rectangle in which the length of one dimension exceeds the other by 500 percent or more. The substrate may have other shapes, however, such that its cross section forms a rectangle in which the length of one dimension exceeds the other by less 500 percent, or the cross section may have a trapezoidal, circular or oval shape.

A substrate such as described above may also be utilized in conjunction with the electrically conductive apparatus of this invention or the encasement of this invention.

In the apparatus of this invention, sensor elements may be located on one or more surfaces of a substrate. Particularly in the case of a multi-layer laminate, sensor elements may be located on two or more surfaces. The materials that are used as the sensor elements may be deposited on different layers of “green”, ceramic tape before the various layers are assembled into a final, cured laminate that constitutes the substrate. The layers on which the sensor elements are located become surfaces of the substrate.

Electrodes may be deposited on the same layers as the sensor elements, or may be-deposited on layers that are on the interior of the substrate and that thus do not become surfaces. Electrodes may thus be located on one, two or more of the surfaces of the substrate, or on none of the surfaces. Moreover, as sensor elements may be located on one, two or more surfaces of the substrate, there may be 4 or more, 6 or more, 8 or more or 10 or more sensor elements on one, two or more surfaces of a substrate. The substrate may thus contain in total 4 or more, 6 or more, 8 or more, 10 or more or 12 or more sensor elements.

In the gas sensitive apparatus, multiple gas sensor elements are used, and they may constitute an array of individually electrically responsive solid state sensor elements mounted in relation to gas input and output means such that an input flow of a gas mixture is passed over all the gas sensor elements substantially simultaneously. It is preferred, but not required, that at least one sensor element is provided for each one of the individual gases in the mixture to be analyzed. As noted above, however, additional sensor elements are also provided to cross check the signals resulting from the sensitivity of an individual element to more than one gas, and this may require a large number of sensor elements. The apparatus may also include a heater for heating the substrate, such as a heating plate or wire mounted on or in the substrate. The heater is powered by a voltage source connected to the heating plate or wire.

Electrical conductivity changes in the sensor elements are caused by electrochemical interactions of the solid surfaces of the sensor elements with adsorbed gas species. The sensor elements may, for example, be prepared from metal oxide semiconductors. Electrical signals resulting from the interaction of gas and sensor surface are extracted as outputs and processed by an analyzer to detect the presence or concentration of various gaseous components in the mixture. Those determinations or computations are achieved by means of a look-up table or by an algorithm-controlled calculator function, or a more sophisticated deconvolution, pattern recognition or neural network technique.

By placing a large number of sensor elements on one or more surfaces of a substrate, by multiplexing the pulse and signal input and output lines, by providing a compact conductive apparatus, and by providing a common amplifier unit and analyzer unit, an analysis of the different gas components in a gas mixture is made possible with a suitably small sensor device.

The small size of an apparatus of this invention permits a sensor device in which it is incorporated to be placed close enough to the source from which the gas is generated that there is no significant change in the composition of the gas mixture between the time at which it is generated and the time at which it reaches the gas sensor device. Any of the apparatus, or the encasement, of this invention may be passed through a circle having a diameter of no more than about 100 mm, preferably no more than about 50 mm, more preferably no more than about 25 mm, and most preferably no more than about 18 mm, making them suitable for use in a small size gas sensor device.

A large number of sensor elements in the apparatus of this invention are accommodated by a multiplexed, space-saving layout of the sensor elements and the electrodes through which pulses and signals flow to and from the sensor elements. The sensor elements may be prepared from chemo/electro-active materials, as described below, and may be placed on one or more surfaces of the substrate. The electrodes may be prepared from metals such as gold, platinum or palladium or a mixture of two or more thereof, and may be placed on or within the substrate. Sensor elements and electrodes on the surface of a substrate may be applied by any of a variety of printing techniques as described below. Electrodes may be placed within a substrate by providing layers of “green”, ceramic tape, one or more of which contain electrodes, and laminating the layers together to form a multi-layer laminate.

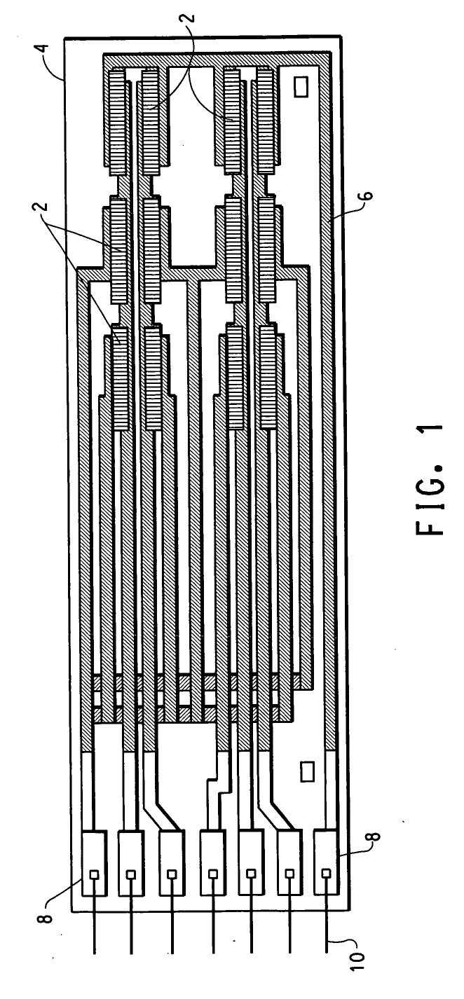

One particular embodiment of a space-saving layout of sensor elements, electrodes and conductors in a gas sensitive apparatus may be seen in FIG. 1. A plurality of sensor elements 2 is provided on a substrate 4. A plurality of electrodes 6 connects the various sensor elements 2 with contact terminals 8. Where because of multiplexing, electrodes are shown crossing each other, that is accomplished by a dielectric layer in between the crossovers.

Electrodes are available to enable completion of an electrical circuit through each sensor element. The contact terminals 8 make contact with conductors 10 to enable passing electrical pulses to, and receiving signals from, the various sensor elements 2. The signals are routed to a microprocessor for handling as described below. In the embodiment of FIG. 1, it may be seen that there are twelve sensor elements and seven conductors, and that the ratio of the number of conductors to the number of sensor elements is 7/12, and that the ratio in such embodiment is thus no greater than about 0.585.

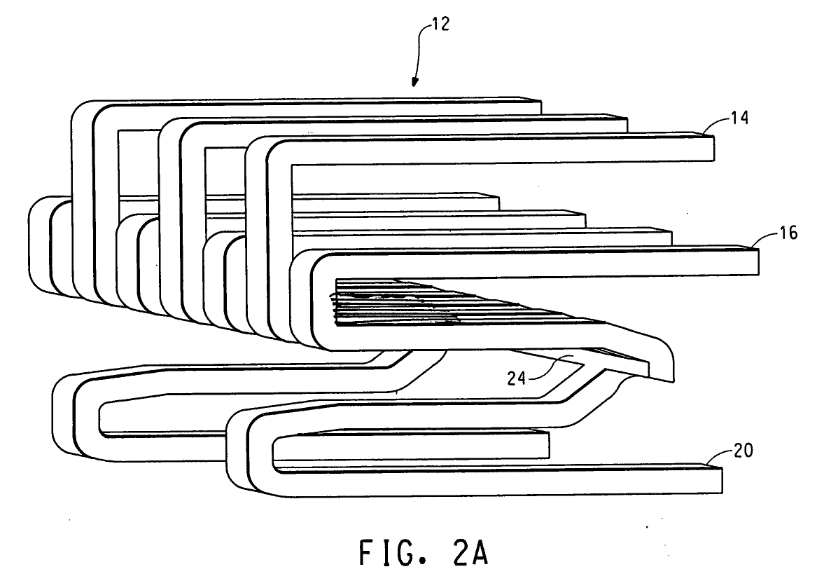

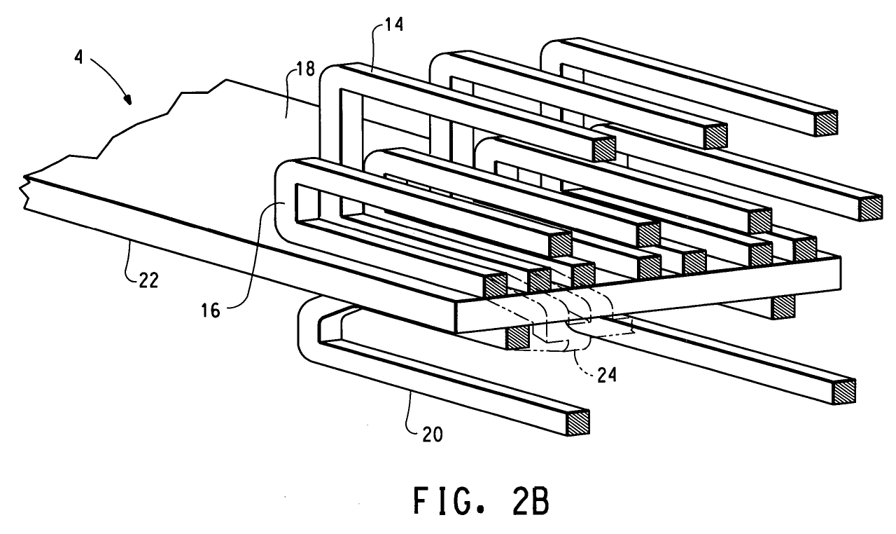

Another embodiment of the gas sensitive apparatus of this invention is shown in FIGS. 2A and 2B, in which the same numbering for the features shown in FIG. 1 is continued where those same features are also shown in either FIG. 2A or 2B. In FIGS. 2A and 2B, a substrate 4 contains a plurality of sensor elements (not shown), and contains the electrodes (not shown) necessary to connect those sensor elements to contact terminals (not shown). A conductor 12 contains a plurality of conductive members 14, and a conductive member 14 contacts a contact terminal on the substrate 4. A first conductive member 16 contacts a first surface 18 of the substrate, a second conductive member 20 contacts a second surface 22 of the substrate, and the first and second conductive members 16, 20 are attached to a common support member 24. Moreover, all conductive members 14 may be attached to the common support member 24. In FIG. 2B, only a portion of the common support member is shown, and that portion is shown in ghost form to permit a better view of the manner in which the conductive members contact the substrate. The respective portions of various conductive members that are attached to the common support member are shown in ghost form for the same purpose.

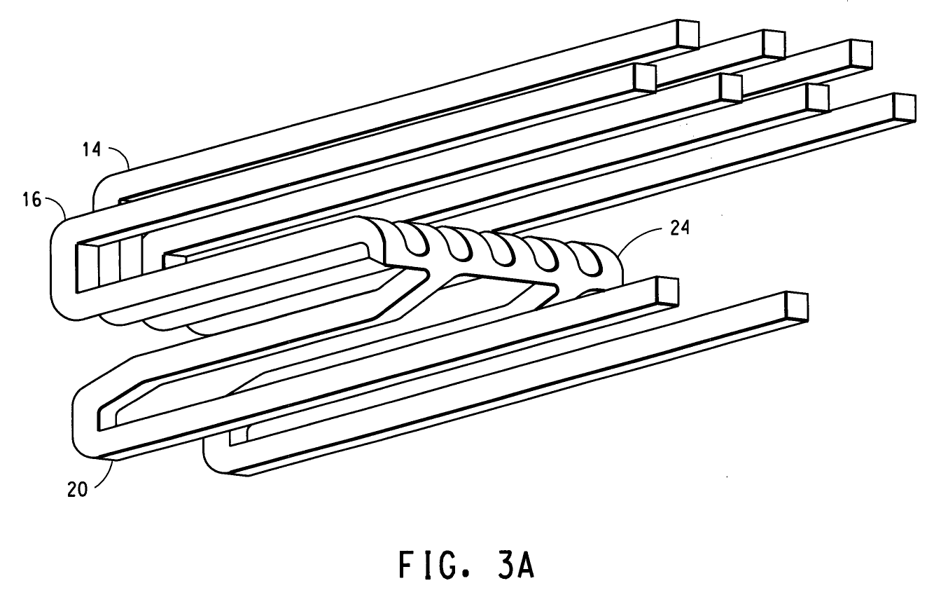

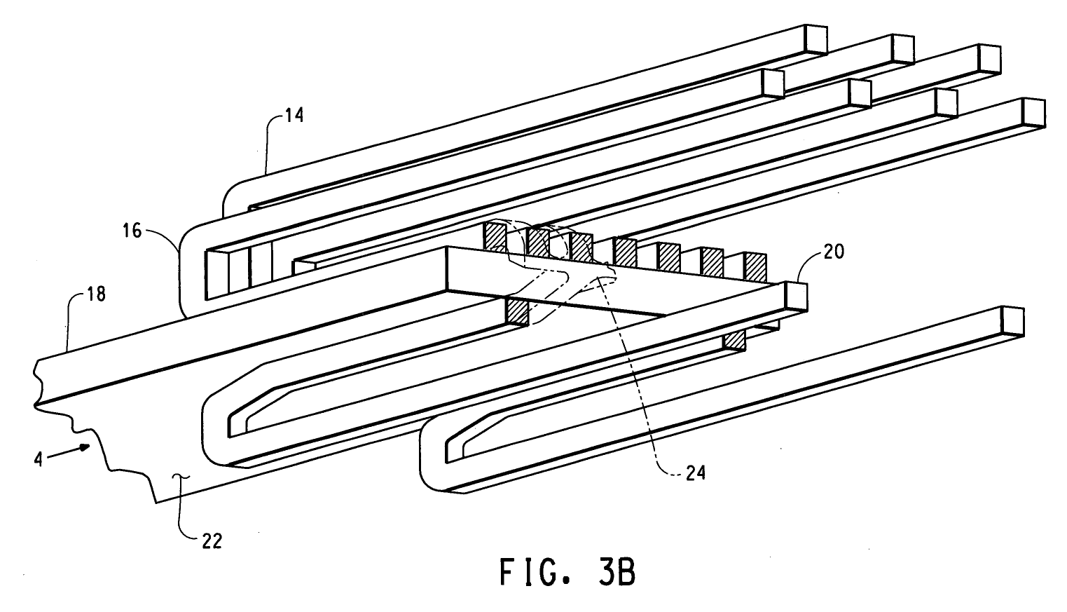

The common support member 24 is better seen in FIG. 3A, in which the same numbering for the features shown in FIGS. 2A and 2B is continued where those same features are also shown in FIG. 3A or 3B. In FIGS. 3A and 3B, it may be seen that not only a first conductive member 16 and a second conductive member 20, but all conductive members 14 are attached to the common support member 24. As in FIG. 2B, in FIG. 3B, only a portion of the common support member is shown, and that portion is shown in ghost form to permit a better view of the manner in which the conductive members contact the substrate. The respective portions of various conductive members that are attached to the common support member are shown in ghost form for the same purpose.

Referring again to FIG. 2B, either the first surface 18, or both the first surface 18 and second surface 22, of the substrate 4 may be said to be contacted by a plurality of conductive members 14. The first surface 18 may be contacted by more conductive members 14 than the second surface 22, and the first surface 18 may be contacted by at least four conductive members 14.

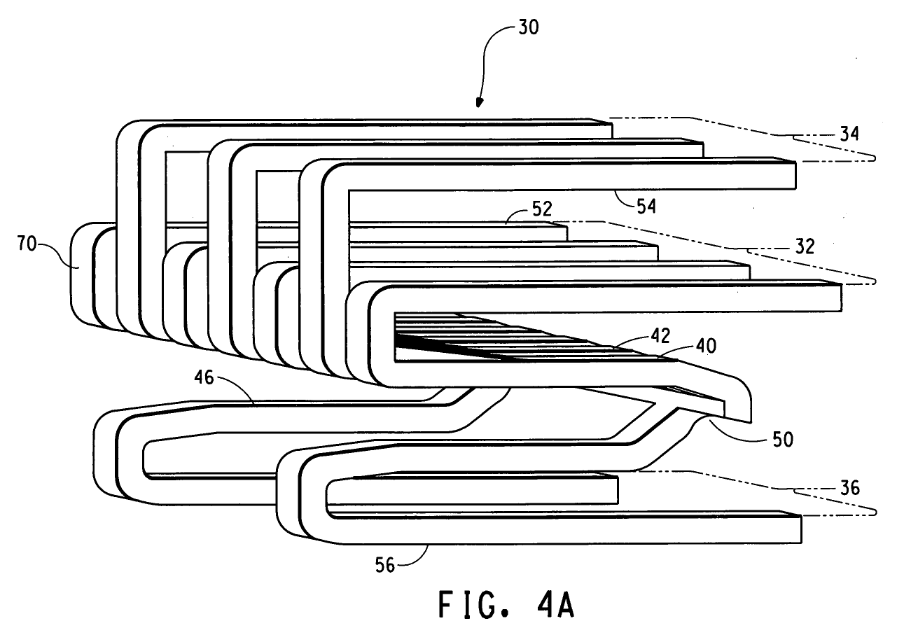

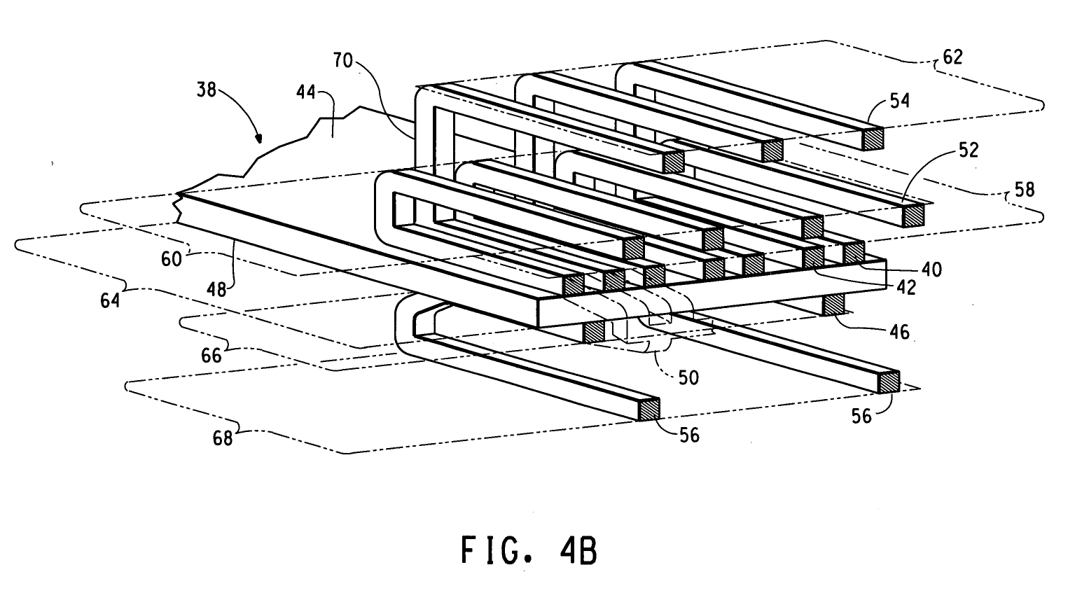

In one embodiment of this invention, the conductor 12 serves as an electrically conductive apparatus, and further views thereof are shown in FIGS. 4A and 4B. The various features of the apparatus shown in FIGS. 4A and 4B may or may not all be present in each of the embodiments of the electrically conductive apparatus of this invention. In FIGS. 4A and 4B, the apparatus 30 has a first set of conductors 32, a second set of conductors 34, and a third set of conductors 36. Each set of conductors contacts a substrate 38 that contains electrodes (not shown).

A first portion 40 of the first set of conductors 32, and a first portion 42 of the second set of conductors 34, is each adjacent or proximate to a first surface 44 of the substrate 38. A first portion 46 of the third set of conductors 36 is adjacent to a second surface 48 the substrate 38. The substrate 38 is carried between the first portions 40, 42 of the first and second sets of conductors 32, 34, and the first portion 46 of the third set of conductors 36. To facilitate this function of the conductors, the first portion of each set of conductors may, if desired, be attached to a common support member 50, but the common support member 50 is not required. As in FIGS. 2B and 3B, in FIG. 4B, only a portion of the common support member is shown, and that portion is shown in ghost form to permit a better view of the manner in which the conductive members contact the substrate. The respective portions of various conductive members that are attached to the common support member are shown in ghost form for the same purpose.

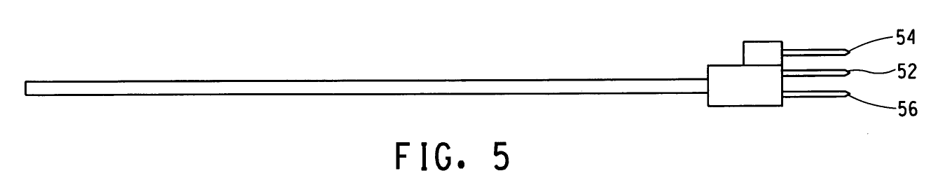

A second portion 52 of the first set of conductors 32, a second portion 54 of the second set of conductors 34, and a second portion 56 of the third set of conductors 36 is removed or distal from the substrate 38. Each of these second portions of conductors is typically connected to an electrical power supply. Another view of the second portion 52, 54, 56 of each of the sets of conductors is shown in FIG. 5.

Referring again to FIGS. 4A and 4B, in one embodiment of the electrically conductive apparatus, the first portion 40 of each of the members of the first set of conductors 32 and the first portion 42 of each of the members of the second set of conductors 34 together define a first plane 58. A second portion 52 of each of the members of the first set of conductors 32 together define a second plane 60 that is separate from and substantially parallel to the first plane. A second portion 54 of each of the members of the second set of conductors 34 together define a third plane 62 that is separate from and substantially parallel to any one or more or all of the first and second planes. The substrate 38 defines a fourth plane 64 that is separate from and substantially parallel to any one or more or all of the first, second and third planes.

The first portion 46 of each of the members of the third set of conductors 36 together define a fifth plane 66 that is separate from and substantially parallel to any one or more or all of the first, second, third and fourth planes. The second portion 56 of each of the members of the third set of conductors 36 together define a sixth plane 68 that is separate from and substantially parallel to any one or more or all of the first, second, third, fourth and fifth planes.

A plane as referred to herein is the imaginary form in space, usually envisioned as a rectangle similar to a sheet of paper, that is defined by the collection of points and lines that all lie within it. There is at least one plane that will pass through, and such plane will thus include certain of the points and lines lying within, each of the following: the substrate 4, the first portion 40 of the first set of conductors 32, the first portion 42 of the second set of conductors 34, the first portion 46 of the third set of conductors 36, the second portion 52 of the first set of conductors 32, the second portion 54 of the second set of conductors 34, and the second portion 56 of the third set of conductors 36.

The condition of two planes being substantially parallel in the apparatus of this invention is satisfied when the planes, if they do intersect, do so at a location that is removed from the closest edge or surface of the apparatus by a distance that is at least about 150 percent of the linear size of the largest dimension of the apparatus; is preferably at least about 300 percent of that largest dimension; and is more preferably at least about 500 percent of that largest dimension.

A bridging portion 70 of each member of the first and second sets of conductors 32, 34 together define a seventh plane (not shown) that intersects any one or more or all of the first, second, third, fourth, fifth and sixth planes.

A member of the first set of conductors 32 may be situated between members of the second set of conductors 34, and a member of the second set of conductors 34 may be situated between members of the first set of conductors 32. The first set of conductors 32 may have more conductors than either the second set 34 or third set 36 of conductors, and in the particular embodiment of FIGS. 4A and 4B, it may be seen that the first set of conductors 32 may have twice as many conductors as the third set of conductors 36. The electrically conductive apparatus is not, however, limited to any particular number of conductors.

In particular embodiments of the electrically conductive apparatus, various different groups of the planes shown in FIG. 4B may be described by their relationship to each other as set forth below. In one embodiment, for example, (a) a first portion 40, 42 of each of the members of the first and second sets of conductors 32, 34 together define a first plane (e.g. the first plane 58 in FIG. 4B), (b) a second portion 52 of each of the members of the first set of conductors 32 together define a second plane (e.g. the second plane 60 in FIG. 4B) that is separate from and substantially parallel to the first plane, and (c) a first portion 46 of each of the members of the third set of conductors 36 together define a third plane (e.g. the fifth plane 66 in FIG. 4B) that is separate from and substantially parallel to the first and second planes.

In another embodiment of the electrically conductive apparatus, however, (a) the substrate 38 defines a first plane (e.g. the fourth plane 64 in FIG. 4B), (b) a portion of each of the members of the first set of conductors 32 together define a second plane (e.g. the second plane 60 in FIG. 4B) that is separate from and substantially parallel to the first plane, and (c) a portion of each of the members of the second set of conductors 34 together define a third plane (e.g. the third plane 62 in FIG. 4B) that is separate from and substantially parallel to the first and second planes.

In a further embodiment of the electrically conductive apparatus, however, (a) a first portion 40, 42 of each member of the first and second sets of conductors 32, 34 is adjacent to a surface of the substrate, (b) a second portion 52 of each of the members of the first set of conductors 32 together define a first plane (e.g. the second plane 60 in FIG. 4B), (c) a second portion 54 of each of the members of the second set of conductors 34 together define a second plane (e.g. the third plane 62 in FIG. 4B) that is separate from and substantially parallel to the first plane, and (d) the first portion 40, 42 of each member of the first and second sets of conductors 32, 34 is attached to a common support member 50.

In yet another embodiment of the electrically conductive apparatus, however, in a further embodiment of the electrically conductive apparatus, (a) a first portion 40 of each member of the first set of conductors 32 contacts a first surface 44 of the substrate 38, (b) a first portion 46 of each member of the third set of conductors 36 contacts a second surface 48 of the substrate 38, (c) a second portion 52, 56 of each member of the first and third sets of conductors 32, 36 is connected to an electrical power supply, and (d) the first portion 40, 46 of each member of the first and third sets of conductors 32, 36 is, attached to a common support member 50.

In the various embodiments of an electrically conductive apparatus described above, the arrangement of conductors such that various sets of them define planes that are separate and substantially parallel to each other is desirable for its usefulness in a compact, space-saving design for the electrically conductive apparatus. When the electrically conductive apparatus is used as a component in a gas sensor device, a corresponding benefit is obtained in that the gas sensor device may be based on a compact, space-saving design as well.

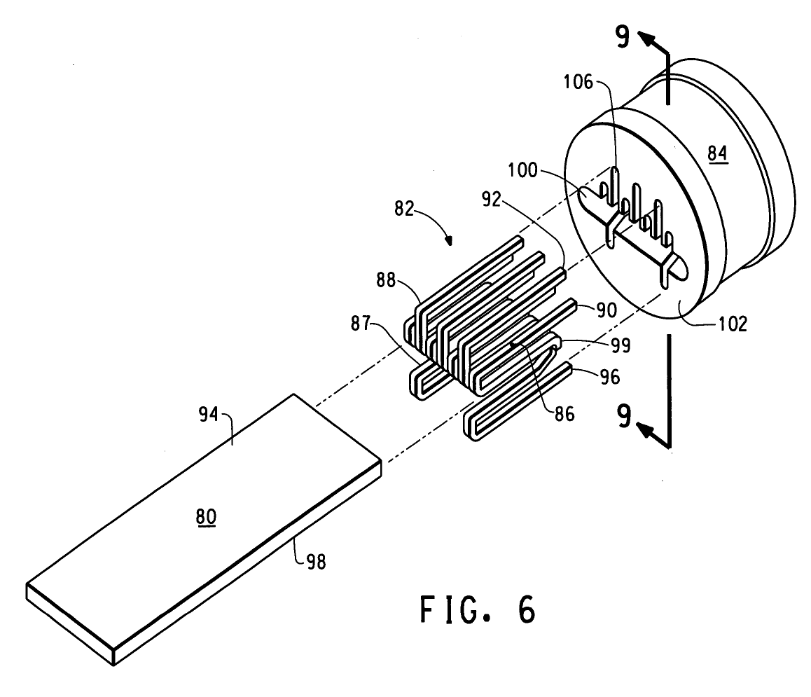

Another embodiment of this invention is an encasement for the electrically conductive apparatus as shown and described above. The encasement of this invention may, however, serve to encase other kinds of electrically conductive apparatus. As may be seen in FIG. 6, a substrate 80 and a plurality of conductive members 82 may be inserted into the encasement 84. Each conductive member 82 may have a first portion 86, which contacts a surface of the substrate 80, and a second portion 88, which is typically connected to an electrical power supply.

There may be different sets of conductive members within the plurality of conductive members 82. For example, the first portion 86 of a first set of conductive members 90, and the first portion 86 of a second set of conductive members 92, may contact a first surface 94 of the substrate 80, and the first portion 87 of a third set of conductive members 96 may contact a second surface 98 of the substrate 80. If desired, the first portion of each set of conductive members may be attached to a common support member 99.

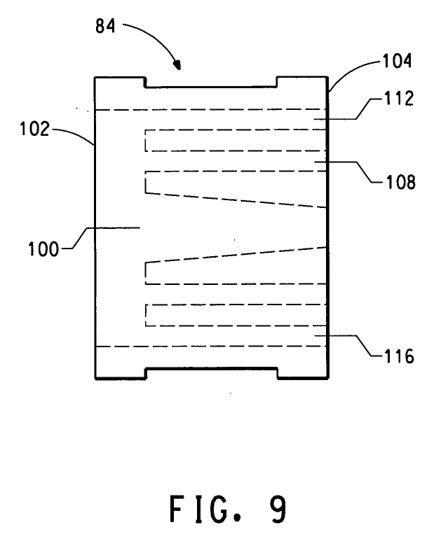

The substrate 80 is carried between the first portions 86, 87 of each of the various conductive members 82. The conductive members 82, with the substrate 80 carried as aforesaid, are received within a shaped aperture 100 of the encasement 84. The shaped aperture 100 is narrowed by a decrease in size moving from the entrance inward toward the back end thereof. This is shown in FIG. 9. The shaped aperture 100 presses the first portion 86, 87 of each conductive member in contact with a surface of the substrate 80 because the conductive members are made of a malleable material such as copper, and insertion of the conductive members 82 and substrate 80 into the shaped aperture 100 requires a press fit. Within the shaped aperture 100, conductive members such as the first and second sets of conductive members 90, 92 are pressed into contact with the first surface 94 of the substrate 80, and conductive members such as the third set of conductive members 96 are pressed into contact with the second surface 98 of the substrate 80. If the first portions of the conductive members are attached to a common support member, the common support member will also be received within the shaped aperture.

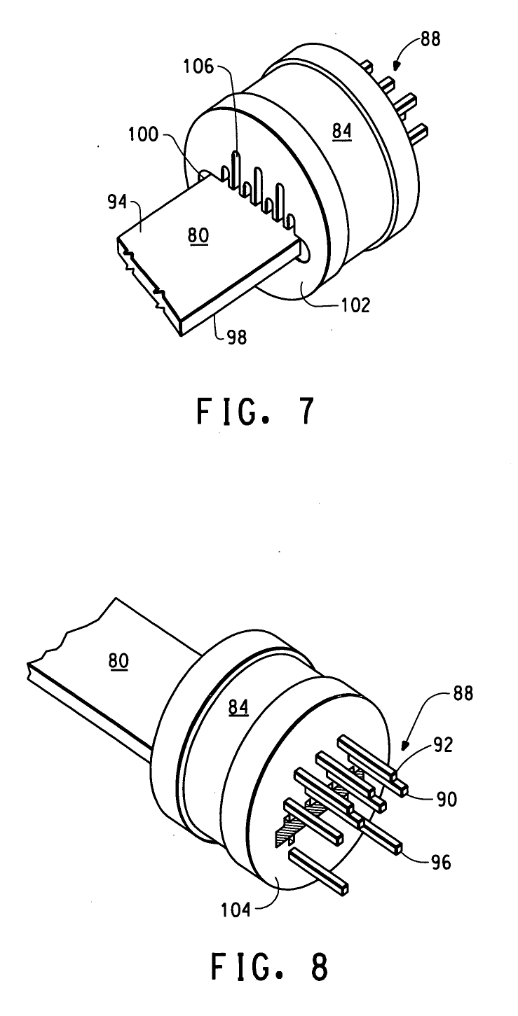

FIG. 7 shows the substrate 80 inserted into the shaped aperture 100 through an opening of the shaped aperture 100 on the front face 102 of the encasement 84, and protruding therefrom. The only portion of the conductive members 82 visible in this view are the second portions 88 of the conductive members 82 seen protruding from the back end of the encasement 84. A better view of the protrusion of the second portions 88 of the conductive members 82 may be seen in FIG. 8, wherein the second portions 88 of the conductive members 82 may be seen protruding from the back end 104 of the encasement 84.

A separate aperture 108 in the encasement 84 is provided for the second portion 88 of each conductive member regardless of which set of conductive members it may be in. The apertures for these second portions of conductive members are visible in ghosted form in the side elevation view of FIG. 9. The apertures 108 for the second portion 88 of each of the members of the first set of conductive members 90 together define a first plane, and the apertures 112 for the second portion 88 of each of the members of the second set of conductive members 92 together define a second plane that is separate from and substantially parallel to the first plane. The substrate 80 defines a third plane that is separate from and substantially parallel to each of the first and second planes.

The apertures 116 for the second portion 88 of each of the members of the third set of conductive members 96 together define a fourth plane that is separate from and substantially parallel to any one or more or all of the first, second and third planes.

A plane is defined by the imaginary lines that would be coincident with the location of the structure of each of the conductive members in a set. A plane as referred to herein is the imaginary form in space, usually envisioned as a rectangle similar to a sheet of paper, that is defined by the collection of points and lines that all lie within it. There is at least one plane that will pass through, and such plane will thus include certain of the points and lines lying within, each of the following: the substrate 80, aperture 100, aperture 108, aperture 112 and aperture 116.

The condition of two planes being substantially parallel in the encasement of this invention is satisfied when the planes, if they do intersect, do so at a location that is removed from the closest edge or surface of the encasement by a distance that is at least about 150 percent of the linear size of the largest dimension of the encasement; is preferably at least about 300 percent of that largest dimension; and is more preferably at least about 500 percent of that largest dimension.

The encasement may be made from a castable, insulating material such as a ceramic.

Other descriptions of the apparatus of this invention, and of methods of use thereof, may be found in U.S. application Ser. No. 09/977,791, filed on Oct. 15, 2001, and in U.S. application Ser. No. 10/117,472, filed on Apr. 5, 2002, each of which is incorporated in its entirety as a part hereof for all purposes.

What is claimed is:

1. A gas sensitive apparatus comprising (a) sensor elements, (b) and conductors that provide electrical current to the sensor elements, wherein the ratio of the number of conductors to the number of sensor elements is no greater than about 0.585.

2. An apparatus according to claim 1 that comprises at least four sensor elements.

3. An apparatus according to claim 1 that comprises at least six sensor elements.

4. An apparatus according to claim 1 that comprises at least eight sensor elements.

5. An apparatus according to claim 1 that has a plurality of surfaces, wherein sensor elements are located on more than one of the surfaces.

6. A gas sensitive apparatus comprising (a) a substrate that comprises a plurality of sensor elements, and (b) a conductor that comprises a plurality of conductive members; wherein (i) a first conductive member contacts a first surface of the substrate, (ii) a second conductive member contacts a second surface of the substrate, and (iii) the first and second conductive members are attached to a common support member.

7. An apparatus according to claim 6 wherein the first surface is contacted by a plurality of conductive members.

8. An apparatus according to claim 6 wherein the second surface is contacted by a plurality of conductive members.

9. An apparatus according to claim 6 wherein all conductive members are attached to the common support member.

10. An apparatus according to claim 6 wherein the first surface is contacted by more conductive members than the second surface.

11. An apparatus according to claim 6 wherein the first surface is contacted by at least four conductive members.

12. An apparatus according to claim 6 wherein the substrate is a unitary body.

13. An apparatus according to claim 6 wherein the substrate is a multi-layer laminate.

14. A gas sensor device comprising a gas sensitive apparatus according to claim 6.

15. A gas sensor device according to claim 14, which is a component in an automotive vehicle.

16. An electrically conductive apparatus comprising first and second sets of conductors that contact a substrate containing electrodes, wherein
(a) a first portion of each of the members of the first and second sets of conductors is adjacent to a first surface of the substrate, and together define a first plane,
(b) a second portion of each of the members of the first set of conductors together define a second plane that is separate from and substantially parallel to the first plane, and
(c) a second portion of each of the members of the second set of conductors together define a third plane that is separate from and substantially parallel to the first and second planes.

17. An apparatus according to claim 16 wherein the substrate defines a fourth plane that is separate from and substantially parallel to one or more of the first, second and third planes.

18. An apparatus according to claim 16 further comprising a third set of conductors, wherein all members of the third set of conductors are adjacent to a second surface of the substrate.

19. An apparatus according to claim 18 wherein the substrate defines a fourth plane; and wherein a first portion of each of the members of the third set of conductors together define a fifth plane that is separate from and substantially parallel to one or more of the first, second, third and fourth planes.

20. An apparatus according to claim 19 wherein a second portion of each of the members of the third set of conductors together define a sixth plane that is separate from and substantially parallel to one or more of the first, second, third, fourth and fifth planes.

21. An apparatus according to claim 16 wherein a portion of each member of the first and second sets of conductors together define a plane that intersects one or more of the first, second and third planes.

22. An apparatus according to claim 16 wherein the portion of the members of the first set of conductors that defines the second plane is connected to an electrical power supply.

23. An apparatus according to claim 16 wherein the portion of the members of the second set of conductors that defines the third plane is connected to an electrical power supply.

24. An apparatus according to claim 16 wherein a member of the first set of conductors is situated between members of the second set of conductors.

25. An apparatus according to claim 18 wherein the first set of conductors has more conductors than either the second or third sets of conductors.

26. An apparatus according to claim 18 wherein the first set of conductors has twice as many conductors as the third set of conductors.

27. An apparatus according to claim 16 wherein the substrate is a unitary substrate.

28. An apparatus according to claim 16 wherein the substrate is a multi-layer laminate.

29. An electrically conductive apparatus comprising first and second sets of conductors; wherein
(a) each set of conductors contacts a surface of a substrate,
(b) a first portion of each member of the first set of conductors contacts a first surface of the substrate,
(c) a first portion of each member of the second set of conductors contacts a second surface of the substrate,
(d) a second portion of each member of the first and second sets of conductors is connected to an electrical power supply, and
(e) the first portion of each member of the first and second sets of conductors is attached to a common support member.

30. An apparatus according to claim 29 further comprising a third set of conductors, a first portion of each of which contacts the first surface of the substrate.

31. An apparatus according to claim 30 wherein the second portion of each of the members of the first set of conductors together define a first plane, and a second portion of each of the members of the third set of conductors together define a second plane that is separate from and substantially parallel to the first plane.

32. An apparatus according to claim 30 wherein the first set of conductors has more conductors than either the second or the third set of conductors.

33. An apparatus according to claim 29 wherein the first set of conductors has twice as many conductors as the second set of conductors.

34. An apparatus according to claim 29 wherein the substrate is a unitary substrate.

35. An apparatus according to claim 29 wherein the substrate is a multi-layer laminate.

36. A gas sensor device comprising an electrically conductive apparatus according to claim 29.

37. A gas sensor device according to claim 29, which is a component in an automotive vehicle.
